(19) United States
(12) Patent Application Publication
(10) Pub. No.: US 2015/0243870 A1
(43) Pub. Date: Aug. 27, 2015

(54) Compact high power density thermoelectric generator

(71) Applicant: Aleksandr S. Kushch, Poway, CA (US)

(72) Inventor: Aleksandr S. Kushch, Poway, CA (US)

(73) Assignee: Hi-Z Technology, Inc.

(21) Appl. No.: 13/999,430

(22) Filed: Feb. 25, 2014

(51) Int. Cl. H01L 35/30; H01L 35/04; H01L 35/32

(52) U.S. Cl. CPC H01L 35/30; H01L 35/32; H01L 35/04

(57) ABSTRACT

A compact high power density thermoelectric generator for producing electric power from a hot fluid heat source. In preferred embodiments the HPD TEGs provide a wide range of electric power generators with a large range of outputs utilizing a modular approach featuring: (1) a basic building TEG block which can be combined with a number of the same type of building blocks to provide (2) a basic TEG section and a number of these basic TEG sections can be combined to provide this wide range of (3) HPD TEG systems. In these preferred embodiments the heat sources could include the exhaust of a truck, car boat, and other generators engines.

### CROSS REFERENCE TO RELATED APPLICATIONS

This application claims the benefit of Provisional Patent Application Ser. No. 61/854,369, filed Apr. 23, 2013.

### FIELD OF THE INVENTION

The present invention relates to thermoelectric (TE) systems and especially to such devices such systems for compact high power density systems for electric power generation.

### BACKGROUND OF THE INVENTION

### Prior Art Thermoelectric Generator Design

FIGS. 1, 2 and 3 show configurations of typical prior art thermoelectric generators (TEGs). These units were designed to produce electric power from the exhaust of a truck and car engines or generate electricity from the burner exhaust as auxiliary power units (APUs). In the first design (FIGS. 1 and 2) the hot exhaust gases exiting a truck engine are directed to pass through an octagonal shaped exhaust duct 2 with fins 4 on the inside to help transfer heat from the exhaust gasses to 72 thermoelectric modules 6 (mounted in eight TE arrays with 9 modules per array) on the outside surface of the exhaust duct. The modules are compressed between the duct and eight water-cooled finned heat sinks 8 with compression system components (not shown). With modules such as the HZ-14 the unit could produce close to about one kilowatt of electric power on a test cell (cooled with city water at approximately 20° C.) and about 530 W was produced when the TEG was installed on the truck (cooled by engine cooler at approximately 90° C.).

FIG. 3 schematically illustrates a TEG that was designed and fabricated for GM Sierra pickup truck. The hot side heat exchanger of this generator features rectangular cross section. Four rows are positioned and compressed between the hot side heat exchanger and heat sinks. Similar TEG designs are presented by various car manufacturers.

All these TEGs are designed in such a way that TE modules are arranged in series/parallel configuration with respect to the heat flow. There are several problems associated with these conventional TEG designs. Four of these problems are presented below:
1. These TEGs were designed with a goal not to exceed the maximum TE module hot side operating temperature (250° C.) that means that the heat transfer and temperature distribution are tied to the maximum (100%) engine load. In a real life engine does not operate with 100% load very often that results in significantly lower hot side temperature and lower temperature differential across the TE modules then the optimal ΔT, which reduced TEG efficiency and electric power output. Under very low engine load or idling, the conventionally designed TEGs practically cannot produce electricity at all or generate electricity very inefficient and expensive.
2. A substantial temperature drop (when engine load is low or when TEG is powered by a burner and works as an auxiliary power generator) in the exhaust gasses as they pass from the TEG inlet to the outlet. This results that the modules near the TEG outlet operate less efficiently than those at the inlet. This also reduces the conventional TEGs efficiency.
3. In order to withstand without deformation compression force of about 200 psi (which is required for good heat transfer) at high temperature and corrosion environment the exhaust duct that acts as a hot side heat exchanger usually is fabricated from special sorts of steel (like Niresist, 3Cr12, Inconel, etc.,) that introduces substantial cost to the TEG system. These materials exhibit low thermal conductivity (20 to 50 W/m° K) that decreases the heat transfer rate compared to aluminum heat exchangers that have thermal conductivity of about 200 W/m° K). Unfortunately, aluminum cannot be used for hot side heat exchangers in conventional TEGs because it starts deforming at temperatures above 250° C. In addition, these hot side heat exchangers are heavy (about three times heavier than aluminum). Conventional TEGs significantly increase the vehicle weight and consume additional fuel during driving. For example, the specific power of the generators described above ranges mostly from 7.0 W/kg to 7.5 W/kg, which means that the weight of 1 kW TEG is approximately 140 kg, which is too heavy for cost efficient automotive waste heat recovery application. It is beneficial to fabricate light weight TEGs in order to improve vehicle fuel efficiency.
4. Every device that is integrated into vehicle exhaust system affects the exhaust backpressure that also impacts engine performance. Unfortunately, the generators that are designed with the goal to maintain low backpressure at 100% load exhibit very limited heat transfer area and cannot efficiently extract heat from the exhaust when engine load is lower. The other words, the conventional TEG can be optimized only for a specific engine for a specific engine load, so these generators inherently cannot be efficiently used for any typical driving engines with typical to cars and truck driving cycles. It is very beneficial to use a generator that can control the exhaust flow rate and efficiently manage the system backpressure and the hot side temperature distribution. In addition, the conventional TEG designs that have series of modules positioned along the exhaust path increase the backpressure problem as additional modules are added to the series. The result is: the more modules the higher the back pressure.

What is needed is a compact high power density thermoelectric generator.

### SUMMARY OF THE INVENTION

The present invention provides a compact high power density thermoelectric generator (HPD TEG) for producing electric power from a hot fluid heat source. In preferred embodiments the HPD TEGs provide a wide range of electric power generators with a large range of outputs utilizing a modular approach featuring: (1) a basic building TEG block which can be combined with a number of the same type of building blocks to provide (2) a basic TEG section and a number of these basic TEG sections can be combined to provide this wide range of (3) HPD TEG systems. The thermoelectric modules may be electrically connected in series or in a combination of series and parallel. In these preferred embodiments the heat sources could include the exhaust of a truck, car boat, and other generators engines. In other embodiments the present invention can be also integrated with various systems having burners utilizing the combustion of materials such as gases, oils, wood, coal. In addition the invention can be applied to stoves to generate electricity simultaneously with cooking, heating or boiling water or technological liquids and solids. The invention can also applied to self-powered appliances (such as space/water heaters) and added to combined heat and power (CHP) electric generating units to produce additional electrical power from hot gasses internal or external to the CHP′ systems. The hot fluid heat source could also be a hot liquid such as hot water or hot oil. The HPD TEGs are also applicable for solar and geothermal power generation applications. \In preferred embodiments the hot fluid heat source is directed through the HPD TEG along multiple parallel paths so that all of the modules are provided with approximately equal hot-side temperatures. All these devices can be assembled from the same or similar major building blocks that are described below.

### BRIEF DESCRIPTION OF THE DRAWINGS

FIGS. 1 and 2 show features of a prior art TEG.

FIG. 3 shows features of a second prior art TEG.

FIGS. 4 and 5 shows a design of a basic building block for construction of sections of a HPD TEG.

FIG. 6 shows a preferred technique for constructing a cooling heat sink.

FIG. 7 shows a first preferred compression technique for creating thermoelectric sandwiches.

FIG. 8 shows a second preferred compression technique for creating thermoelectric sandwiches.

FIGS. 9 and 10 show a first preferred TEG building block comprising 12 modules one hot-side heat exchanger (with rectangular passages) and two cooling heat sinks.

FIG. 11 shows a second preferred TEG building block comprising 12 modules and one hot-side heat exchanger with circular passages).

FIG. 12 shows a TEG section utilizing the building block of FIG. FIGS. 9 and 10.

FIG. 13 shows a HPD TEG comprised of two of the TEG section shown in FIG. 12.

FIG. 14 shows a cut-away view of a HPD TEG comprised of four of the TEG section that are equipped with 96 TE modules.

FIG. 15 shows a HPD TEG comprised of four of the TEG sectionwith 96 TE modules.

FIG. 16 shows a waste heat recovery system, which is assembled with two TE sections, each section is equipped with 16 TE modules

FIG. 17 shows an electric power generating water heater.

FIG. 18 shows a power generating stove.

FIG. 19 shows a power generating stove for space heating.

FIG. 20 shows a power generating stove with a hot plate.

FIG. 21 shows a field portable HPD TEG.

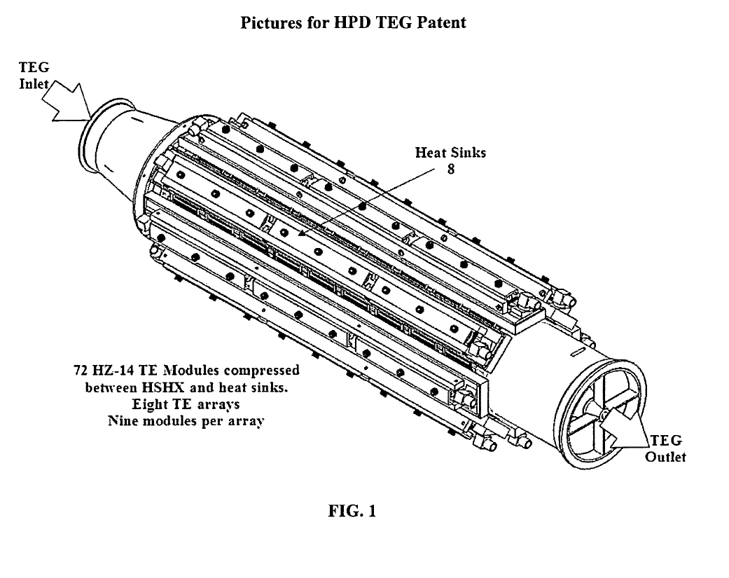

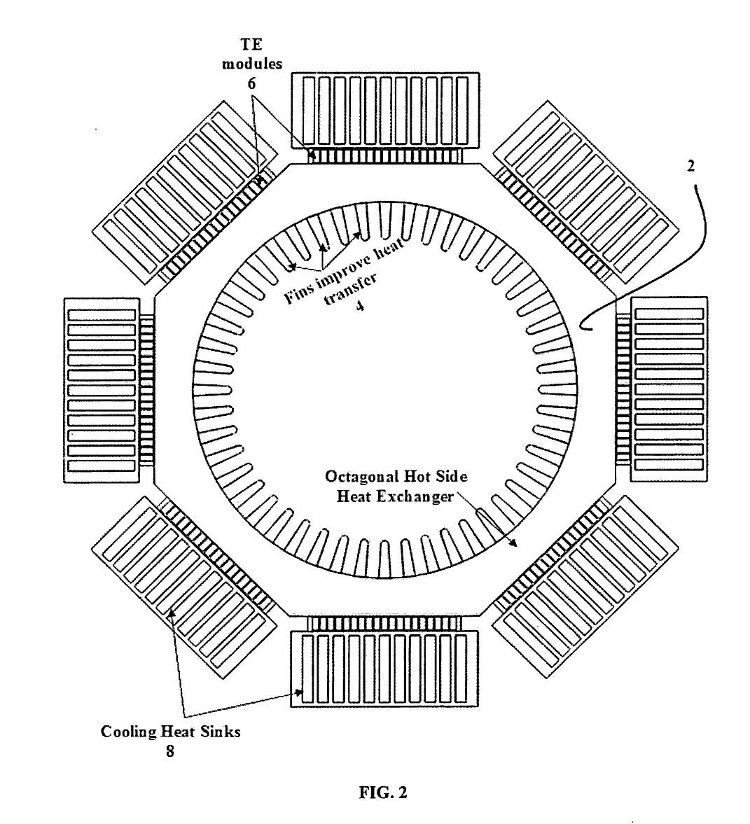

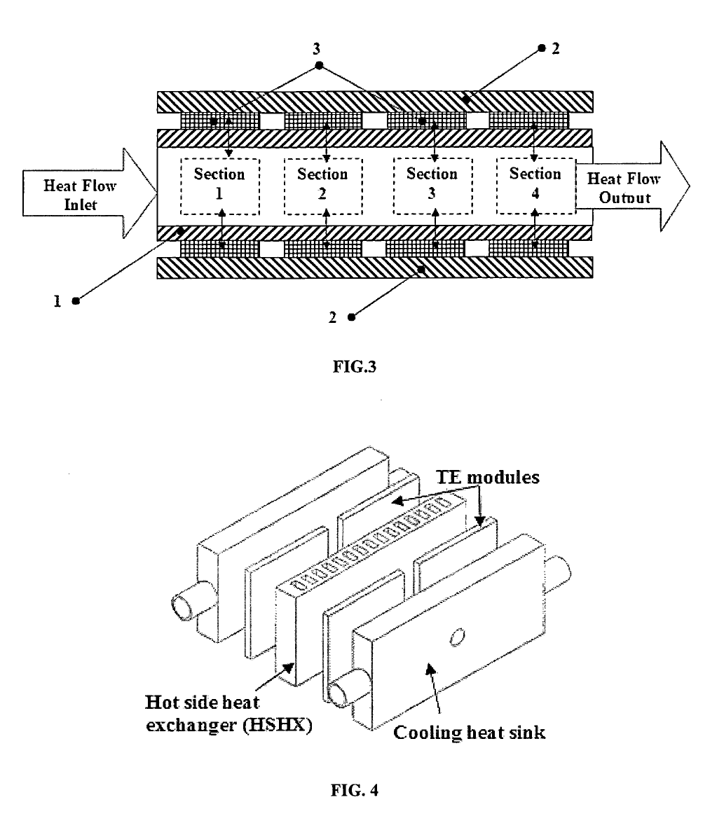

### DETAILED DESCRIPTION OF PREFERED EMBODIMENTS

In preferred embodiments TE generators can be assembled to provide a wide range of outputs utilizing a modular approach featuring: (1) a basic building TEG block which can be combined with a number of the same type of building blocks to provide a (2) basic TEG section and a number of these basic TEG sections can be combined to provide this wide range of (3) HPD TEG systems.

### TEG Building Blocks

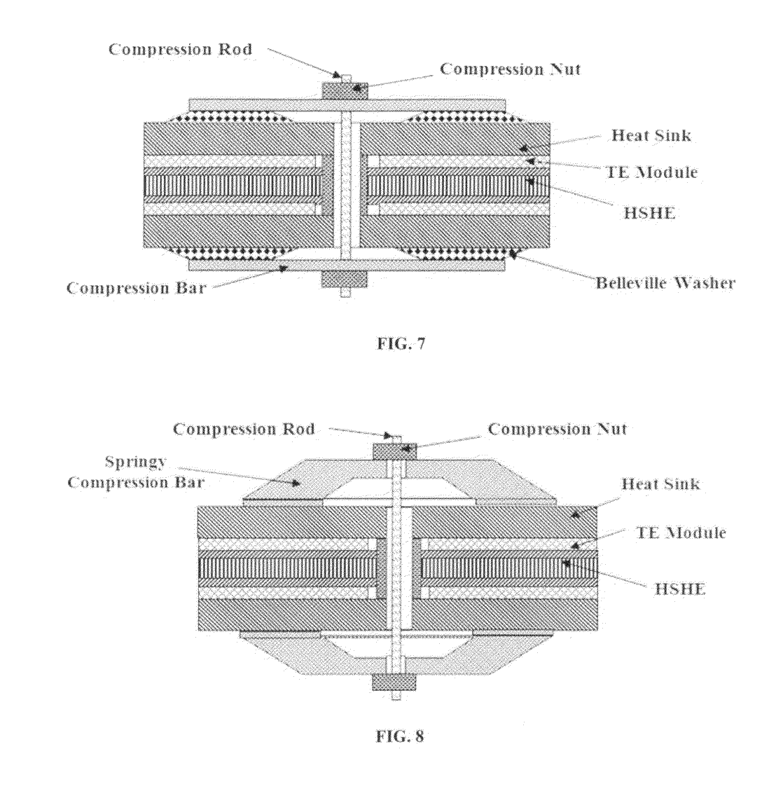

In a preferred embodiment the basic building block of various thermoelectric generators can be assembled from at least one hot-side heat exchanger, a plurality of thermoelectric modules, and a plurality of liquid cooling heat sinks as shown in FIGS. 4, 5 and 6. All these components are compressed together by a compression system as shown in FIGS. 7 and 8.

In this embodiment the smallest TEG building block is assembled with four thermoelectric modules that are sandwiched between the hot side heat exchanger and heat sinks. The hot side heat exchanger (HSHX) can be fabricated from various materials, including copper, aluminum, steel, ceramic and combination of above.

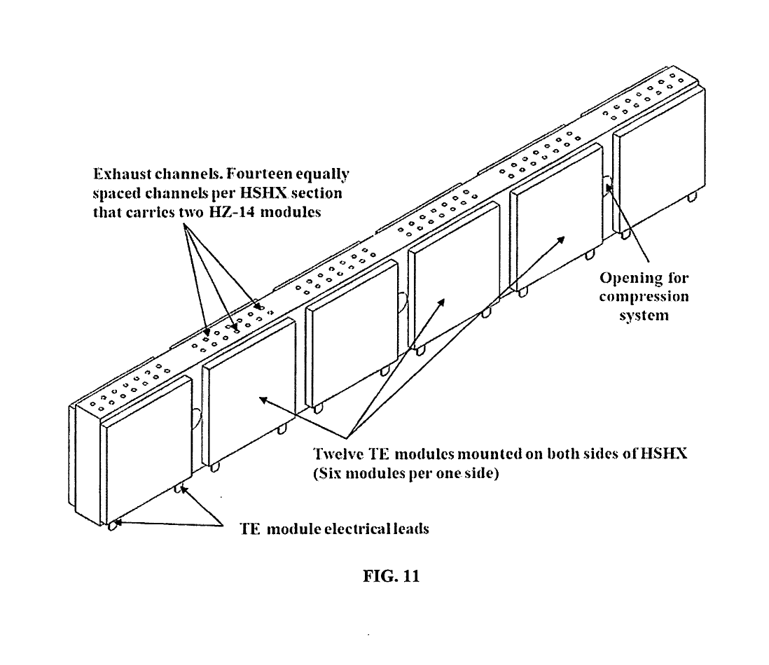

The HSHX in equipped with extended surfaces to provide for efficient heat transfer from the hot exhaust to the TE modules. In the FIG. 4 example, the extended heat transfer surfaces is produced by rectangular cross section passages (with dimensions ˜3 inch by 7 inch). In the FIG. 11 example the extended surfaces are provided by a large number of circular holes in an aluminum block. Extended surfaces can be made from pins, fins and other geometries.

The liquid cooled heat sinks (cold plates) are positioned on the TEG building block cold side in order to effectively reject heat from the TE modules. One of the possible heat sink designs is presented in FIG. 6. This heat sink is made from aluminum block with three drilled channels. Two horizontal channels are connected by a vertical channel. The vertical channel has a threaded plug on one end, so the cooling water enters one channel horizontal and exits from the other horizontal channel as shown in FIG. 6. Liquid turbulizers (not shown) can be inserted into the channels in order to improve heat transfer. The central (solid part) of the heat sink is equipped with an opening for positioning a compression rod when the HPD TEG section is assembled.

This preferred heat sink design will provide for efficient and inexpensive cooling option for HPD TEG, but the other heat sink designs, including air cooled systems can be integrated into the HPD TEG. The air cooled system can be employed the same way as liquid heat sinks by using high efficiency heat transfer devices, for example heat pipes or pyrolytic graphite structures or other high thermally conductive materials or devices. In this case heat rejected from the TE modules will be transferred to appropriate place for dissipation to ambient.

The TE modules are preferably sandwiched between the HSHX and heat sinks and compressed at approximately 200 psi by a compression system (not shown). The compression system can be assembled from a threaded rod, nuts, Belleville washers and flat washers or springy compression components as illustrated in the two techniques shown in FIGS. 7 and 8.

The modules are separated from all electrically conductive surfaces with a thermal interface electrically insulating material. The thermal interface materials preferably provides good thermal conductive but electrically insulation. These include many available ceramics and polymers, or composite materials.

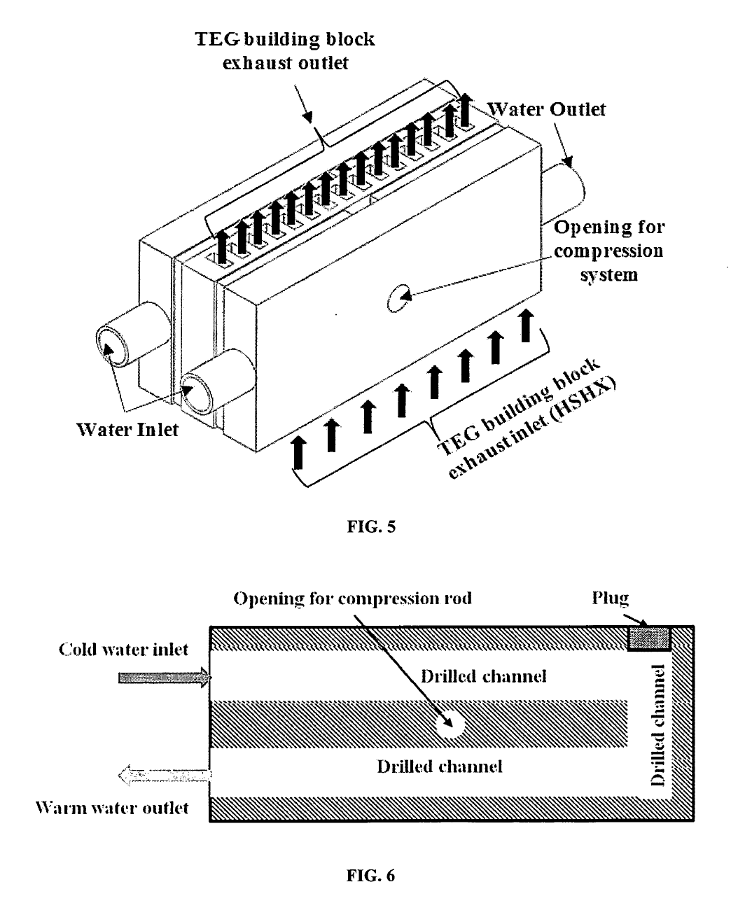

The building block is positioned in such a way that the exhaust from the heat source is entering the hot side heat exchanger from one side and exits the HSHX from the other side as shown in FIG. 5.

In HPD TEGs the exhaust always travels through the distance that is equal to one TE module length. It does not matter how many modules are employed into the TEG system, all the modules are positioned in parallel with respect to the heat flow that ensures uniform hot side temperature distribution among all the modules. This creates fundamentally different effect in scaling up TEGs (compared to the conventional TEGs). In these embodiments the addition of modules to the designs actually decreases the hot gas back pressure.

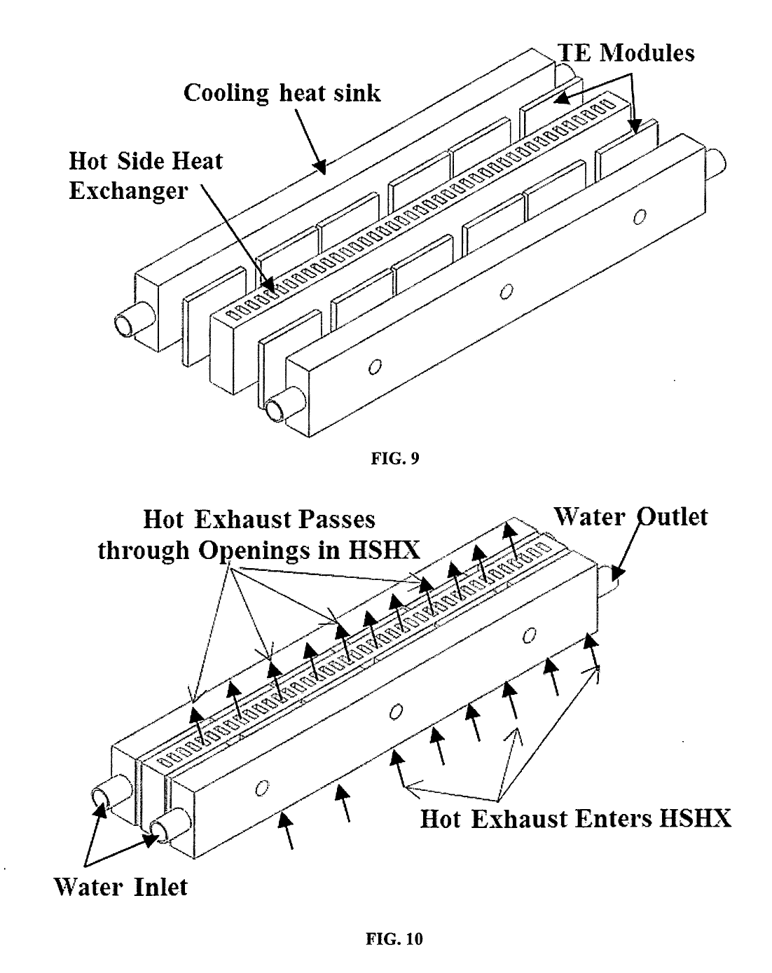

The same approach can be used to fabricate larger TE building blocks. This technique is scalable and multi kW system can be assembled with the same components. For example, FIGS. 9 and 10 present a TE building block that is assembled with one HSHX, two heat sinks and 12 TE modules (6 TE modules per side of the HSHX).

### TEG Sections

The TEG sections can be assembled by alternating HSHXs and heat sinks as shown in FIG. 10. The advantage of fabricating larger systems comes from the idea of sharing both sides of the hot side heat exchanger and heat sinks for TE modules positioning. As the results, (as shown in FIGS. 4, 5, 9, and 10) the number of heat sinks in the TEG section assembly is equal to the number of the HSHX+1. Other TEG designs assume the use of two heat sinks per each HSHX. Such high power density (HPD) TEG uses fewer components (that reduces the TEG cost) and the TEG became lighter (because less components are used and ability to use lightweight aluminum HSHXs), which is important for automotive waste heat recovery systems.

A slotted cover can be used on both sides of the TEG section (not shown). The cover will protect the cooling heat sinks from direct contact with hot exhaust on the bottom section of the TEG section. This reduces the amount of heat that flows from the exhaust to cooling system. Parasitic heat flow reduction results in smaller and less expensive TEG section cooling system. If this type of TEG section is integrated, for example, with a cook stove, the reduction of parasitic heat losses from the exhaust to coolant results in more heat delivered to the cooking food.

Preferably a cover plate on the top section of the TEG integrated into cooking appliances to prevent spilled water/food to damage TE modules and/or electrical connections between modules.

### TEG Systems

Various HPD TEG systems can be assembled by integration small or large TEG sections in a single unit or integration one or several HPD TEG sections with various heat sources. A list of possible TEG systems containing HPD TEG sections are presented in the Table 1 below:

TABLE 1
HPD TEG Possible Applications

| HPD TEG System | TEG Sections Employed | Applications |
|---|---|---|
| Large multi-kW WHR | Large kW size TEG sections assembled | Trucks, buses, marine of |
| systems and APUs, | with 10 to 20 W TE modules. Multiple | road vehicle WHR, |
| CHPs | sections employed, TE sections mostly | military WHRS and APUs |
| Medium 100-1,000 W | Medium (100-300 W) TE sections mostly | Cars, pickup trucks, vans, |
| WHR systems and | assembled with 1-20 W TE modules. | boats, military generators, |
| APUs, CHPs | Mostly one/two sections employed | residential CHPs |
| Selfpowered appliances | Small/medium (50-100 W) TEG sections | Remote & emergencies |
| (space water heaters), | assembled with (1-10 W) modules. | heating, hot & boiling |
| small AUPs | Mostly one/four sections employed | water source, power gen. |
| Combined cooking and | Small (20-200 W) TEG sections | Third world, emergencies, |
| power generation | assembled mostly with 1-5 W TE | remote, campers, food, |
| | modules. Mostly single TE sections | water, power generation |

### Preferred Embodiment

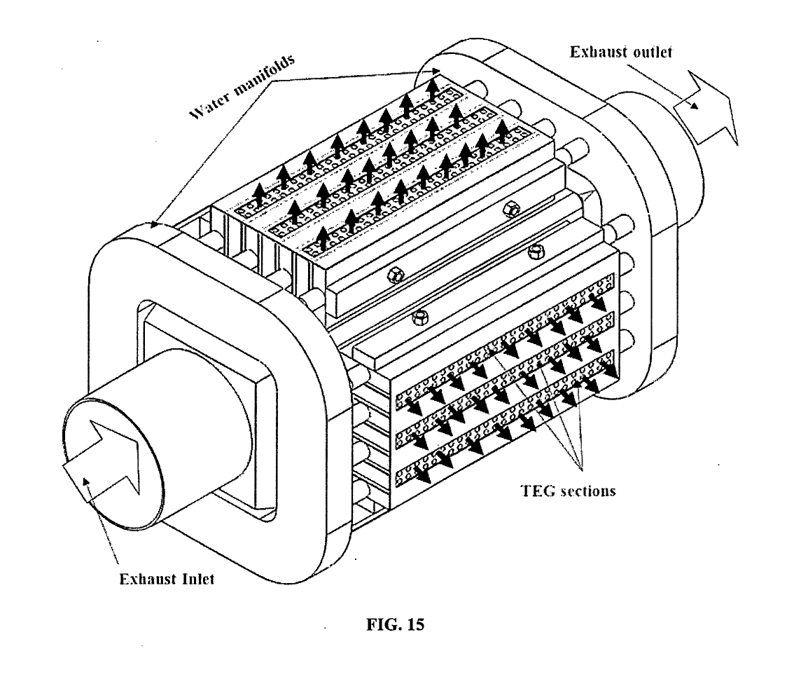

The multi-kilowatt waste heat recovery system that can be used for the large trucks, buses, marine engines, and stationary applications is presented in FIGS. 13, 14 and 15. These systems can also be used as an auxiliary power unit for military, commercial and emergency applications or could be a part of combined heat and power (CHP) systems.

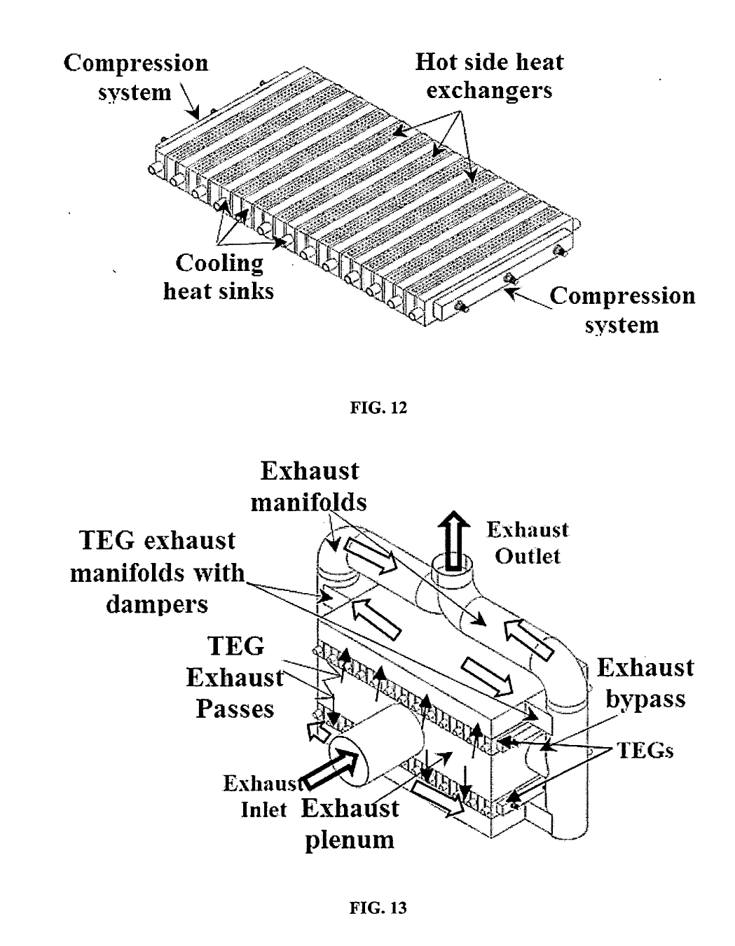

The FIG. 13 system is assembled from two identical 2 kW TEG sections integrated in a single unit as presented in FIG. 12. Each TEG section is assembled from building blocks shown in FIGS. 9 and 10.

The cooling system of this waste heat recovery unit can be integrated with the engine cooling system or can be configured an independent cooling system with a dedicated radiator, a pump and a fan.

The TEG sections that is presented in FIGS. 9 and 10 and in FIG. 11 are assembled with 12 HSHX (each HSHX caries 12 HZ-14 modules. Total number of HZ-14 modules in this assembly is 144, that makes possible to generate 2.058 kW of electric power per section at standard operating conditions (ΔT=200° C.). This TEG section is very compact (20″W×17″D×2.5″H), the volume is 0.49 ft³ and the power density is 4.20 kW per ft³). For comparison, the 1 kW generator that was developed for class 8 Diesel track waste heat recovery occupies 1.6 ft³ that translates to the power density of 1/1.6=0.625 kW/ft³.

If similar TEG section is fabricated with HZ-20 modules instead of HZ-14 TEM, capacity of such a section will be 2.98 kW with the dimensions of 20″W×20″D×3″H. The power density of such TE section is 4.29 kW/ft³.

In order to verify that the proposed HSHX design is capable of delivering the adequate amount of thermal energy for TE modules the following calculations and assumptions are made. Engine parameters are presented in the following Table 2.

TABLE 2
Engine parameters

| Engine | | | Intake | Exhaust | Exhaust |
|---|---|---|---|---|---|
| model | RPM | HP | CFM | temperature, ° F. | flow, CFM |
| Cummins, 6CT | 2200 | 300 | 742 | 1000 | 2140 |

Assuming that the HSHX is fabricated from aluminum plate with the cylindrical exhaust channels (individual exhaust channel diameter is 0.0025 m). The aluminum plate dimensions are 42.5 cm L×7 cm W×1.9 cm H. Fourteen cylindrical exhaust channels are made for each section of two HZ modules as shown in FIG. 12 A.

Based on HZ-14 thermoelectric module properties (available at Hi-Z's website Ref.⁷), at Tₕₒₜ=250° C. and T_{cold}=50° C., it is necessary to deliver 257 W to each module to produce 14.29 W of electric power per individual module. It means that for each section on the HSHX that carries two HZ-14 modules it is necessary to deliver 514 W of heat. The heat transfer area that is adequate to deliver 514 W to two HZ-14 modules can be calculated from basic heat transfer equation (1):

Q=h×A×(Th−Tc), where (1)

Q—is amount of heat transferred to modules (514 W)
h—is the heat transfer coefficient, W/(m²K)
A—is the heat transfer area, m²,
Th—is the exhaust temperature, ° C., (537° C. from Table 2)
Tc—is the HSHX temperature, ° C. (targeting for ˜265° C. to maintain ˜250° C. on TE modules hot side)

The heat transfer area can be calculated from equation 2 as:

A=Q/h*ΔT or 514W/h*272 (2)

The heat transfer coefficient can be calculated by equation 3.

h=k*Nu/D_{H}, where (3)

Nu—is the Nusselt number (dimensionless),
D_{H}—is the hydraulic diameter (for cylindrical channel D_{H} is equal the channel diameter)

The Nusselt number can be calculated from Dittus-Boelter correlation 4.

Nu=0.023*Re^{0.8}*Pr^{0.33}, where (4)

Re—is the Reynolds number, and
Pr—is the Prandtl number

The Reynolds number is calculated by equation 5.

Re=ρ*v*D_{H}/μ, where (5)

ρ—is the exhaust gas density (ρ=0.435 m³/kg at ˜537° C.)
v=exhaust velocity, m/s,
D_{H}—hydraulic diameter (0.0025 m), and
μ—is the dynamic viscosity, Pa*s (0.000037 at ˜537° C.)

The Prandtl number is calculated by equation 6.

Pr=Cₚ*μ/k, where (6)

Cₚ—is the exhaust specific heat, J/kg*° K (Cₚ=1100 J/kg*° K at 537° C.),
μ—is the dynamic viscosity, Pa*s (0.000037 at 537° C.), and
κ—is the thermal conductivity of the exhaust, W/m*° K, (κ=0.0577 W/m*° K at 537° C.)

Solving the set of equations 1 to 6 provides an estimate of heat to each set of two HZ-14 modules. The results of these calculations are presented in Table 3.

TABLE 3
Heat Transfer Calculations

| PARAMETER | VALUE |
|---|---|
| Channel Diameter, m | 0.0025 |
| Channel height (h), m | 0.07 |
| Channel area, m\hat{ }2 | 4.90625E−06 |
| HX area (one channel) | 0.0005495 |
| Number of channels per two modules | 14 |
| Total HX area, m\hat{ }2 | 0.007693 |
| Total number of channels | 2016 |
| Exhaust flow m\hat{ }3/s | 0.000500992 |
| Velocity, m/s | 102.113032 |
| Dynamic viscosity, μPas | 0.000037 |
| Thermal conductivity κ (exhaust), W/m ° K | 0.0577 |
| Specific heat Cp, J/kg ° K | 1100 |
| Density (exhaust), kg/m\hat{ }3 ρ at 800° K | 0.435 |
| Re | 3001.295199 |
| Pr | 0.705372617 |
| Nu | 12.40374826 |
| h | 286.2785099 |
| T hot, ° C. | 537 |
| T cold, ° C. | 265 |
| dT | 272 |
| Area required for heat transfer, m\hat{ }2 | 0.006600935 |
| HSHX/Required area ratio | 1.165440928 |

The analysis of the heat transfer calculations indicates that the proposed HSHX design satisfies the heat transfer requirements. The heat transfer area exceeds the requirements by 16.5% that ensures delivering 514 W of heat to the set of two HZ-14 modules.

This example of heat transfer calculations is not an attempt to optimize the HSHX design. The optimized design will be efficient for a specific engine with the specific load, exhaust temperature and flow rate. It is much more convenient to optimize the TEG operation by controlling the ratio of the exhaust flows through the TEG and the bypass line. In this case the TEG can be adjusted to operate efficiently for wide range of engine parameters as well as for various engines.

### Operation

The exhaust from the engines, burners or other sources enters the exhaust plenum that is equipped with two TEG sections (top and bottom sides of the exhaust plenum). The exhaust flow can exit the exhaust plenum via two options: 1) the two TEG sections through 24 HSHXs and/or 2) two bypass manifold (one on each side). The bypass manifolds are equipped with the dampers (not shown in FIG. 13) that allow to direct all the exhaust through the TEG sections (when the dampers are completely closed) or distribute the exhaust flow between the two TEG sections and two bypass manifolds (when dampers are partially or completely open). The four TEG exhaust manifolds are also equipped with four dampers (not shown in FIG. 13) that allow controlling exhaust flow through the TEG sections.

These multiple dampers (exhaust flow control system) allow managing the TEG hot side temperature and the system backpressure in very wide ranges of the exhaust parameters (flow rate and temperature). This enables using the same waste heat recovery system integrated with various engines and ensures optimal TEG operation within wide range of specific engine operating regimes.

When engine/burner exhaust enters the exhaust plenum and the bypass dampers are completely closed, the exhaust flow splits on 24 streams and each stream enters 24 hot side heat exchangers. With the uniform pressure distribution in the exhaust duct, hot side heat exchangers and exhaust manifolds, the flow rates and temperatures of all 24 streams will be practically the same. Under these conditions, the hot side of all 288 modules will experience nearly the same hot side temperature, which maximizes the TEG efficiency.

Because the open area of the TEG hot-side heat exchangers is larger or equal to the exhaust inlet area, the TEG backpressure maintains low and, if necessary could be even lower than the backpressure of the exhaust pipe.

If the waste heat recovery system is coupled with the engine that produces more exhaust energy (higher flow rate and temperatures) than necessary to be delivered to the TEG sections to produce the designed amount of electric power, the temperature of the TEG hot side and the backpressure are growing accordingly. In this case the dampers in the exhaust bypass ducts can be partially opened, to allow a portion of the exhaust to escape the system without entering the TEG section. This results in lowering both, the TEG hot side temperature and the system backpressure.

Finally, if a relatively small waste heat recovery system is installed in a very large engine and with completely open bypass dampers the TEG hot side temperature is still exceeds the design level, the TEG dampers can be partially closed in order to reduce the exhaust flow though the TEG sections until the hot side temperature meets the required value.

The system can be easily automated by integrating the hot side TEG temperature sensor/pressure sensor and actuators that adjust the damper positions based on temperature/pressure settings. The ability to precisely control the TEG hot side temperature allows using aluminum or other light weight alloys as the hot-side heat exchanger materials. This makes the waste heat recovery system lighter, less expensive and exhibits significantly better thermal conductivity compared to traditional types of steel that typically used to fabricate hot-side heat exchangers.

This system can be easily scaled up and down by using the following approaches:

TABLE 4
HPD TEG Scale Up and Down Options

| Scaling Down | | Scaling Up | |
|---|---|---|---|
| Approach | Results | Approach | Results |
| 1. Use smaller capacity | Produces less | 1. Employ larger modules | Produces |
| modules | power, reduces | 2. Design larger TE sections | more power, |
| 2. Employ shorter TE blocks | dimensions, | (4 . . . 6 . . . 8 . . . 12 . . .) | saves more |
| 3. Employ less TEG sections | weight and | 3. Integrate more TE sections | fuel, reduces |
| | cost | 4. Employ several identical | pollutant |
| | | TEGs with the same exhaust | emissions |
| | | source | |

Applicants expect that the proposed high power density TEG system will be an extremely cost effective for the following reasons:
1. HPD TEG eliminates many complicated parts of the conventional TEG designs. Larger number of identical components (hot side heat exchanger and heat sinks) is less expensive to fabricate compared to a variety of different parts. The balances of this system are: a frame that holds TEG sections, the transition parts, manifolds and a shell (optional).
2. The number of the heat sinks will be drastically reduced compared to the TEGs that employ two heat sinks per one hot side heat exchanger or individual heat sink per a TE array; the number of the heat sinks integrated into the HPD TEG is equal to the number of the heat exchangers plus one. The number of the compression systems is also reduced. In the TEGs that were developed for military waste heat recovery application one compression system serves to compress four modules. In the proposed HPD TEG that is presented in FIG. 7 three compression systems serve 144 modules. If the TEG is design with the approach similar to the mentioned above military TEG, it will require employing 36 compression systems.
3. Employing aluminum or other light weight alloys for hot side heat exchangers will be less expensive solution than steel because of the difference in the cost of metals and less cost of machining aluminum/alloys.
4. The hot-side heat exchanger and heat sink designs make fabrication of them very simple and inexpensive. The hot side heat exchanger will be made from an aluminum bar with a set of drilled holes for the exhaust gases or cast aluminum can be used. The heat sinks will be also made from aluminum bars with two drilled channels along the axis and one drilled hole that connects the two axial channels. One opening will be plugged after the heat sink is machined. The schematic drawing of the heat sink cross section is presented in FIG. 6. In addition, the major HDP TEG components (HSHXs and heat sinks) can be manufactured by casting processes instead of machining them from metal blocks. This could reduce the TEG cost
5. Since the HPD TEG is a much simpler device as compared to prior art designs, it will require less labor to be assembled.

The advantages of the HPD TEG approach are summarized below:
1. Compact TEG design due to reduced number of many bulky components (such as heat sinks, compression systems, etc.)
2. Significantly weight reduction due to:
   Reduced number of components (heat sinks, compression systems, etc.),
   Fabrication hot side heat exchanger from aluminum
3. Reduced system cost as described above
4. Simplicity of assembly
5. Versatility of design configurations, suitable for any vehicles and other heat sources
6. Scalability—small (few Watts) and large (multi-kilowatt) TEGs can be built with the same approach and components.

### Other HPD TEG Embodiments

### Multi-Kilowatt WHR/APU System

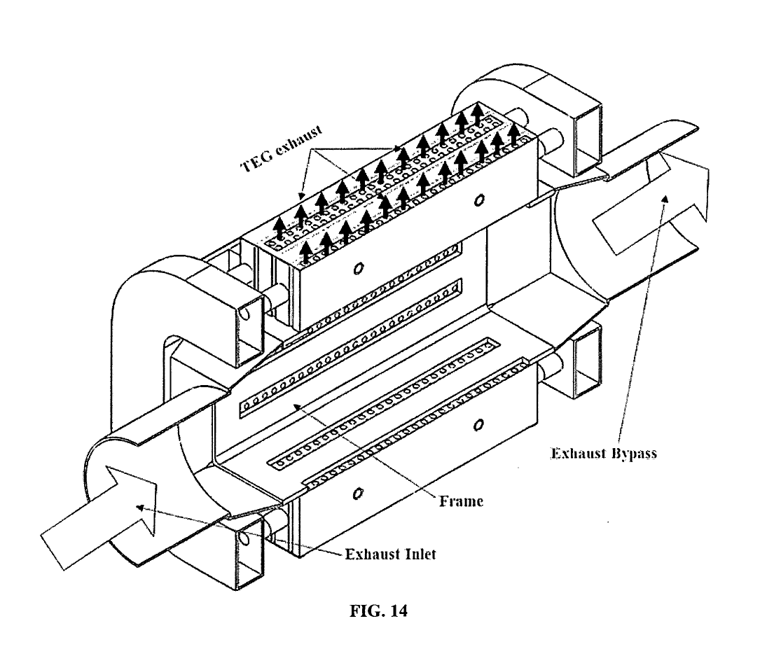

The example of the multi-kilowatt waste heat recovery/APU system is schematically presented in FIGS. 13 and 14. This is a nominal 2 kW (at ΔT across the modules=200° C.) TEG device. This TEG is assembled from four identical TEG sections. Each section contains tree HSHXs and four heat sinks. Each HSHX carries eight TE modules (four HZ-20 modules on each side) that totals in 24 HZ-20 modules per each section. Two compression systems are employed per each section.

Each TEG section produces nominal (at ΔT=200° C.) power of 497 W, the entire unit will produce nominally 1,988 kW. The TEG system also employs the central frame (optional) and two water manifolds (inlet and outlet).

The TEG sections are attached to the central frame, which is equipped with the slots that match the dimensions and the pattern of the openings in the hot-side heat exchangers of the each TEG section. At the same time the, solid sections of the central frame are blocking the cooling heat sinks, preventing the parasitic heat sinks heat loads. The gaskets made from ceramic materials, mice or other suitable materials can be positioned between the central frame and the TEG sections. The openings in these gaskets shall match the openings pattern of the central frame. These gaskets provide for gastight connections between the TEG sections and the central frame.

The four TEG sections can be also integrated together with various fixtures directly. In this case the central frame can be excluded from the system design. The cooling manifold provide for the coolant flow in and out of the TEG system.

The 2 kW TEG can be used for various waste heat recovery systems, as an APU or a part of the CHP system.

### Medium size HPD TEG Waste Heat Recovery/APU

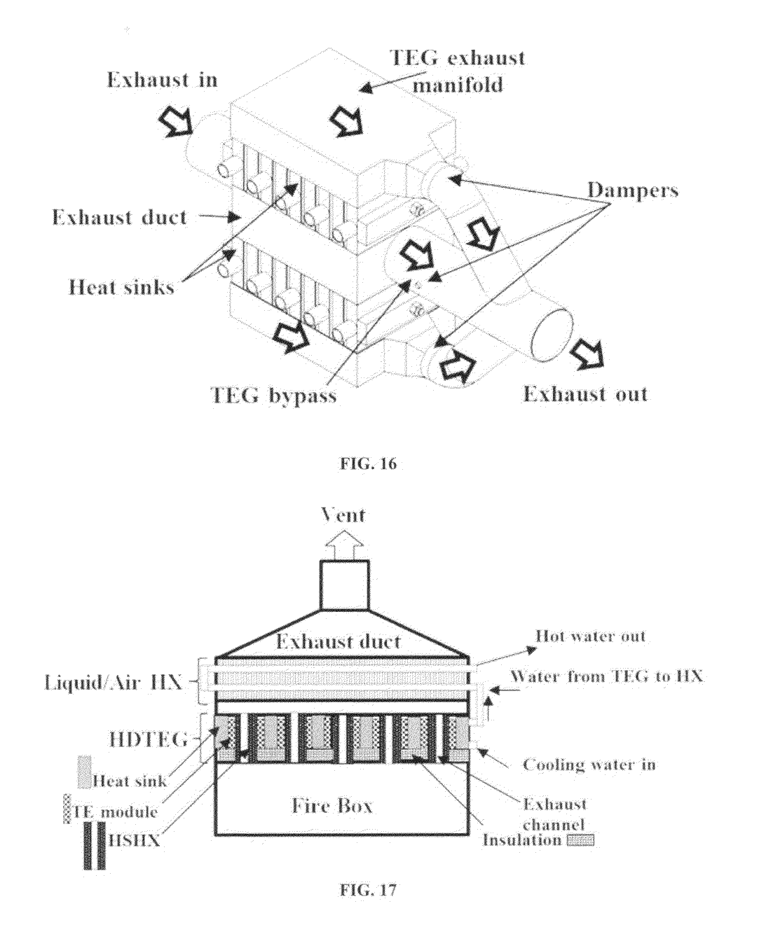

The medium size waste heat recovery system that also can be used as an auxiliary power unit is presented in FIG. 16. The medium size system configuration is similar to the large size system. The difference is only that the TEG sections are significantly smaller—each TEG section is assembled with four Hot side heat exchangers (each heat exchanger carries four HZ-20 modules) and five heat sinks, so the total number of HZ-20 thermoelectric modules is 32, which means that the HPD TEG nominal power is about 660 W. Taking into account that the car/pickup truck manufacturers are mostly targeting for a waste heat recovery systems capable of producing about 300 W of the electric power, this kind of the TEG will perfectly fit to this applications. (When the engine coolant is used to cool the TEG, the TEG capacity is about 50% of the nominal).

The medium size HPD TEG is also equipped with the set of dampers in order to optimize TEG efficiency and operates very similar to the large size HPD TEG.

### Self-Powered Appliances

Various self-powered appliances can be built based on HPD TEG approach. One of the possible options is described below:

### Power Generating Water Heater

The power generating water heater, which is presented in FIG. 17 employs a single HPD TEG section that is positioned at the exit of a fire box (combustion chamber), which is equipped with a gas/oil/wood or other fueled heat source.

Downstream of the HPD TEG section a liquid/air heat exchanger is installed. Hot exhaust passes the exhaust channel of the Hot-side heat exchanger and a portion of heat is absorbed by the hot-side heat exchanger and transferred to the TE modules that are sandwiched between the hot-side heat exchanger and heat sinks. Cold water enters the heat sinks through a manifold (not shown in FIG. 16) and rejects heat from the cold side of the modules. Slightly preheated water exits the HPD TEG system and enters the air/liquid heat exchanger. The burner exhaust passes the HPD TEG though the openings in the hot side heat exchanger. The exhaust that is coming out from the TEG is still very hot. It is anticipated that less than 20% of the thermal energy is extracted by the hot-side heat exchanger, the rest of the exhaust energy enters the air/liquid heat exchanger and heats preheated in the HPD TEG water. The power generating heater can be fabricated in two versions: 1) self-powered water heater that produces electric power just to provide for the self-powered feature, and 2) the water heater that generates surplus electricity that can be used for various purposes (charge battery, power electronics, lighting, computers, phones, TVs, radios, etc.

The first option (self-powered water heater) will be less expensive, because smaller HPD TEG will be employed. For example, a commercially available instantaneous water heater manufactured by Rinnai, Model Number REU-VB2735FFUD-US generates up to 200,000 Btu (58.6 kWhr.) using natal gas or propane. For the steady state operation this water heater requires 83 W of electric power. It means that if the HPD TEG will produce approximately 100 W of electric power, the water heater will be operating in the self-powered mode and producing about 17 W of surplice electric power.

It is possible to fabricate 100-watt HPD TEG from 40 HZ-2 commercial modules. These 40 modules can be positioned on five hot-side heat exchangers (eight modules per hot-side heat exchanger, four modules on each side). The dimensions of such 100-watt HPD TEG will be 8.5″W×5″L×2.5″H, the footprint area of 42.5 square inch. The horizontal cross-section of the water heater is 14″×9.6″, which results in area of 134.4 square inch. Theoretically if the HPD TEG is fabricated using all available space (134.4 square inch), it is possible to fabricated the HPD TEG with the capacity of 316 W. This means, that this water heater potentially can produce up to 233 W of surplus electric power if larger HPD TEG is built.

In order to generate 100-watt of electric power about 2 kW of thermal power has to be transferred to the HPD TEG. For the self-powered water heater 2 kW of thermal power accounts for only 2/58.6=0.034 or 3.4% from nominal water heater heat input. Even if the largest HPD TEG is installed in such water heater, it will require less than 10% of heat input to be transferred to the TEG. Such very low hot-side heat exchanger required efficiency means that the hot-side heat exchanger does not require to have an extended heat transfer surface (simple and inexpensive hot-side heat exchanger design) and the hot-side heat exchanger shall be a device with very low backpressure, acting as some kind of an exhaust and/or flame spreader that is located between the combustion chamber and air/liquid heat exchanger.

The described above power generating water heater can be used as a hot water and electricity source in remote locations (showers, hydronic heating systems) or during electrical outages. The ability to produce surplus-electricity could be extremely important, for example to power life assisting medical devices (for example oxygen generators, etc.,) when for any reasons electric power is not available.

### Power Generating Stove with Hot Water Tank

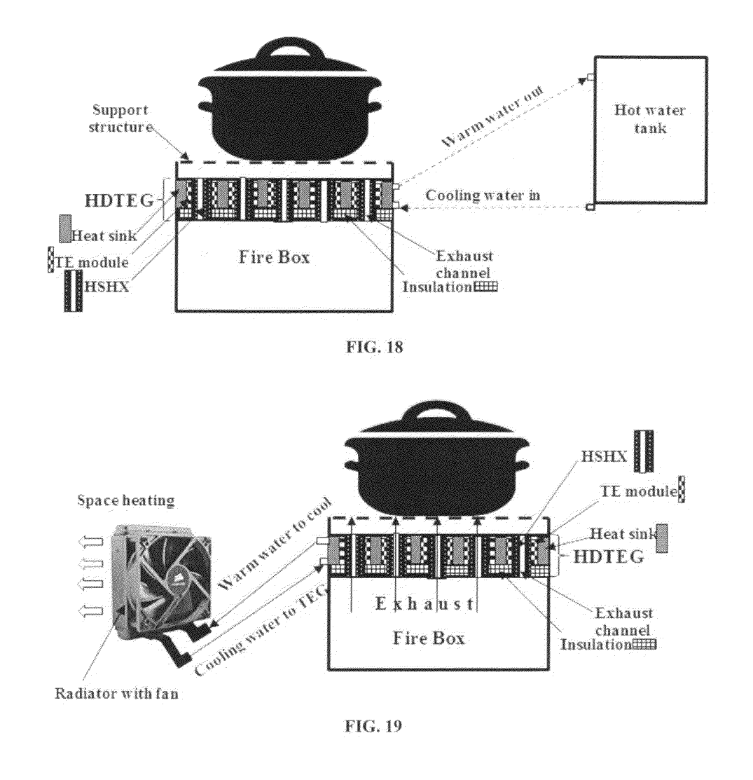

The HPD TEG can be a part of any type of stove acting as exhaust or flame spreader and power generating device as shown in FIG. 18. The hot exhaust from the gas or oil burner passes the hot-side heat exchanger and cooks food. Part of the exhaust heat is delivered to the TE modules and converted to electricity. The temperature of the TEG hot side can be controlled by the burner firing rate. Also, in order to provide for a uniform temperature distribution over the TEG area, it is possible to install a flame/exhaust flow divider between the flame zone and the TEG.

In order to provide for a free exhaust flow through the TEG, the various (rings, rectangular, triangular, polygonal, standoffs or other geometry spacers) can be positioned on a top of the TEG and acting as a support for pans, kettles, and other cookware. Similar designs can be used, for example, for process heating liquid or solid materials or other purposes.

The HPD TEG that is integrated into the system is similar that described above. The HPD TEG with a footprint area of 12″×12″ potentially can produce about 300 W of electric power, which is sufficient to power lighting system for a large house and run TVs, computers, charge batteries, etc. It can be a single power source in the remote locations, developing countries and emergency situations. In addition to power generation, the system will produce hot water for various purposes. If necessary, multi-kW HPD TEG can be fabricated for integration with stoves. In order to produce one kW of electric power with HZ-2 modules, the stove with hot plate of 3 square foot is needed (footprint is 21″×21″) The 1-2 kW HPD TEG systems can be fabricated to satisfy needs in electricity for an individual home.

If larger TE modules are integrated into the HPD TEG the multi-kW power sources can be made with smaller footprint. For example, if HZ-20 modules are used to build the HPD TEG, in order to produce 1 kW of electric power (at ΔT=200° C.) it is necessary to incorporate 48 modules into the TEG. This number of modules can be carried by six hot side heat exchangers (eight per HSHX, four on each side). The HPD TEG section will feature the following dimensions: (11″ wide×13″ long×3″ high). Only one square foot of stove top can produce one kilowatt of electric power.

Such kilowatt/multi-kilowatt HPD TEGs could be a key part of a residential combined heat and power generating system.

The cooling agent of this system can be water of other liquids. If hot water is needed (for dishwashing, showers, etc.), a water tank can be integrated into the system as shown in FIG. 18. The water can circulate by the natural convection or a special pump can be installed to provide for water circulation.

### Power Generating Stove with a Radiator

The power generating stove that is equipped with a radiator can be used for cooking, electric power generation and space heating as shown in FIG. 19.

The radiator size and cooling fan can be sized to meet the HPD TEG heat rejection and space heating requirements. The system can be equipped with a pump to provide for water (coolant) circulation. All the electrical devices can be driven by the TEG power. The energy storage (battery or other) can be included in the system to provide for quick system startup. The battery is also can be charged by the TEG.

### Power Generating Stove with a Hot Plate

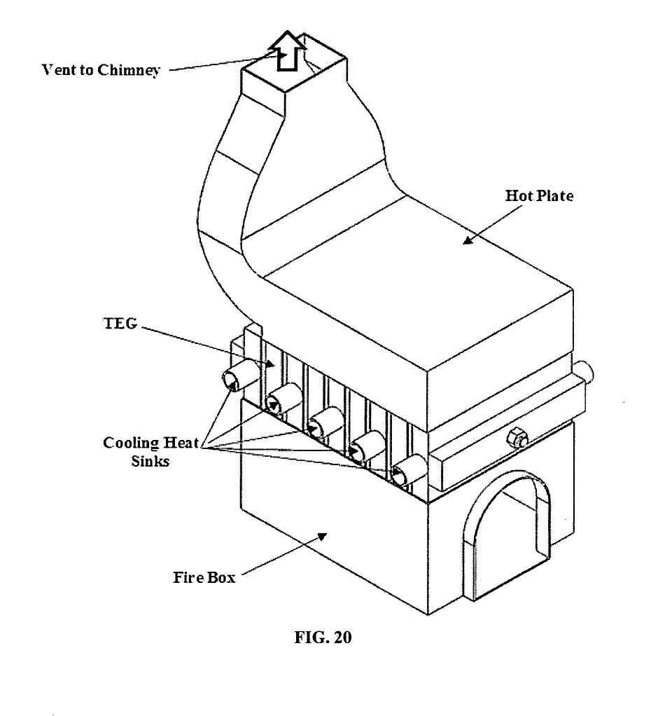

The power generating stove that is equipped with the hot plate is presented in FIG. 20. This stove can use wood or coal, but the gas or liquid burner can be also installed inside of the fire box. The exhaust from the fire box is passing the HPD TEG and heats the stove hot plate. By the natural draft or exhaust fan the exhaust is evacuated via a vent. The HPD TEG is operating that same way as described above and any of the cooling system (tank, radiator or others) can be integrated with this system.

### Field Portable HPD TEG

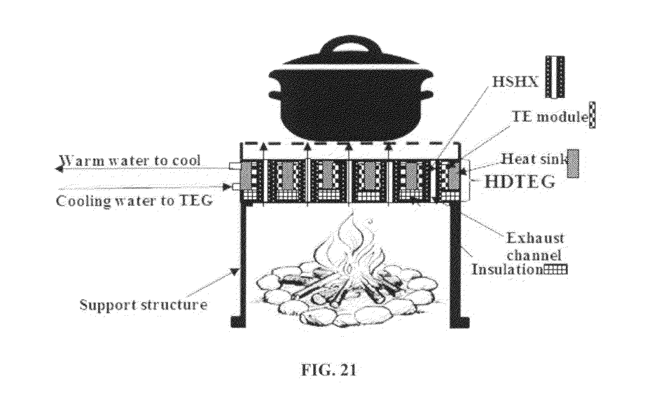

The HPD TEG section can be used for field power generation/emergency/campers/development counties, etc. The TEG section can be carried separately and installed on a support structure in the field as shown in FIG. 21. Detachable walls can be included in the system in order to ensure a stable combustion flame in windy or rainy environment.

The HPD TEG section can be designed to generate the required amount of electric power. Various TE modules can be integrated into this system and various cooling systems (mentioned above or others) can be used.

### Other Variations

Persons skilled in the thermoelectric art will recognize that many possible variations of the specific examples described above and in the figures. So these examples should be considered as preferred embodiments of the present invention and the scope of the present invention should be determined by the claims and their legal equivalence.

What is claimed is:

1. A compact high power density thermoelectric generator (HPD TEG) for producing electric power from a hot fluid heat source comprising:
A) at plurality of similar thermoelectric sections arranged to provided a hot-fluid plenum into which and out of which a hot fluid will flow, each of the similar thermoelectric sections being comprised of:
1) a plurality of basic thermoelectric generator building blocks, each basic building block being comprised of:
a) at least one hot-side heat exchangers defining a number of hot-side heat exchangers and adapted to provide a plurality of high surface area passage ways for the hot fluid to pass out of the hot fluid plenum,
b) a number of at least two cooling heat sinks, wherein the number of cooling heat sinks is equal to at least the number of hot-side heat exchangers plus one,
c) a plurality of thermoelectric modules, each defining a hot side and a cold side, sandwiched under compression between a hot-side heat exchanger and a cooling heat sink;
2) at least one cooling fluid inlet and at least one cooling fluid outlet,
B) structural elements providing:
1) a hot fluid inlet plenum providing a passage way for hot fluid to enter the hot fluid plenum and
2) a first hot fluid outlet plenum comprised of structural elements adapted direct flow of hot gas passing through the high surface area passage ways of the at least one hot-side heat exchanger;
C) electrical circuitry adapted to connect electrical output of at least a portion of the plurality of thermoelectric modules to provide a desired electrical output of the HPD TEG.

2. An HPD TEG as in claim 1 wherein the at least one hot-side heat exchanger in each building block is a plurality of hot side heat exchangers.

3. An HPD TEG as in claim 1 wherein the extended surfaces in the at least one hot-side heat exchanger are provided by a plurality of rectangular passage ways.

4. An HPD TEG as in claim 1 wherein the extended surfaces in the at least one hot-side heat exchanger are provided by a plurality of circular passage ways.

5. An HPD TEG as in claim 2 wherein the at least one hot-side heat exchanger in each building block is at least ten hot side heat exchangers.

6. An HPD TEG as in claim 2 wherein the at least one hot-side heat exchanger in each building block is one hot side heat exchanger.

7. An HPD TEG as in claim 2 wherein the at least one hot-side heat exchanger in each building block is at least 12 hot side heat exchangers.

8. An HPD TEG as in claim 1 wherein the number of thermoelectric sections is at least two thermoelectric sections.

9. An HPD TEG as in claim 1 wherein the number of thermoelectric sections is at least 4 thermoelectric sections.

10. An HPD TEG as in claim 1 wherein the number of thermoelectric sections is four thermoelectric sections with each sections comprising three hot side heat exchangers and four heat sinks with each of the four hot side heat exchangers providing heat energy to eight 20-watt thermoelectric modules with the HPD TEG adapted to provide a nominal two-kilowatt electrical output with a 200° C. temperature differential.

11. An HPD TEG as in claim 1 wherein the number of thermoelectric sections is two thermoelectric sections with each section comprising four hot side heat exchangers and five heat sinks with each of the four hot side heat exchangers providing heat energy to four 20-watt thermoelectric modules with the HPD TEG adapted to provide a nominal 660-watt electrical output with a 200° C. temperature differential.

12. An HPD TEG as in claim 1 wherein the HPD TEG is a component of a water heater adapted to produce at least 100-watts of electrical power from the temperature differential between cold water entering the water heater and hot water in the water heater.

13. An HPD TEG as in claim 1 wherein the hot fluid is exhaust of an engine.

14. An HPD TEG as in claim 2 wherein the engine is an internal combustion engine.

15. An HPD TEG as in claim 1 wherein each of the plurality of thermoelectric modules in the building block positioned in parallel with respect to flow of the hot fluid through one of the high surface area passage ways to assure uniform hot side temperature among all of the modules in the building block.

16. An HPD TEG as in claim 1 wherein the similar thermoelectric sections are designed to produce a reduced back pressure of the hot fluid with the addition of sections.

17. An HPD TEG as in claim 1 wherein the HPD TEG is a component of a combined heat and power system adapted to produce useful heat and electric power.

18. An HPD TEG as in claim 1 wherein the HPD TEG is a component of a combined heat and power system adapted to produce electric power and useful heat for space heating and water heating.

19. An HPD TEG as in claim 1 wherein each module is comprised of less than 64 legs.

20. An HPD TEG as in claim 1 wherein each module is comprised of less than 49 legs.

21. An HPD TEG as in claim 1 wherein each module is comprised of less than 36 legs.

22. An HPD TEG as in claim 1 and further comprising a bypass device adapted to permit a portion of the hot fluid to bypass the high surface area passage ways so as to provide temperature control for the thermoelectric modules.

23. The HPD TEG as in claim 22 wherein the hot side heat exchangers are comprised of aluminum.

24. The HPD TEG as in claim 1 wherein the thermoelectric modules are electrically connected in series or parallel or combination of above.

25. The HPD TEG as in claim 1 and further comprising flow turbulizers in the heat sinks.

26. The HPD TEG as in claim 1 and further comprising flow turbulizers in the hot side heat exchangers

27. The HPD TEG as in claim 1 wherein the similar thermoelectric sections are interconnected in such a way that they form an exhaust duct.

28. The HPD TEG as in claim 1 wherein the hot side heat exchangers and the heat sinks are fabricated from materials chozen from the following group of materials: aluminum, aluminum magnesium alloys, copper, steel, ceramic, composite materials.

29. The HPD TEG as in claim 1 wherein a plurality of components the heat sinks are manufactured by die or investment casting.

30. The HPD TEG as in claim 1 wherein a plurality of components the hot side heat exchangers are manufactured by die or investment casting.
